(19) United States
(12) Patent Application Publication
(10) Pub. No.: US 2026/0182416 A1
(43) Pub. Date: Jun. 25, 2026

(54) REDISTRIBUTION LAYER SUBSTRATE AND MANUFACTURING METHOD THEREOF

(71) Applicant: REALTEK SEMICONDUCTOR CORP., HsinChu (TW)

(72) Inventors: Shih-Chieh Su, HsinChu (TW); Chia-Jen Chou, HsinChu (TW); Nai-Jen Hsuan, HsinChu (TW)

(73) Assignee: REALTEK SEMICONDUCTOR CORP., HsinChu (TW)

(21) Appl. No.: 19/363,950

(22) Filed: Oct. 21, 2025

Related U.S. Application Data
(60) Provisional application No. 63/711,319, filed on Oct. 24, 2024.

(30) Foreign Application Priority Data
May 5, 2025 (TW) 114116834

(51) Int. Cl. H01L 23/498; H01L 21/48; H01L 23/00

(52) U.S. Cl. CPC H10W 70/65; H10W 42/121; H10W 70/05; H10W 70/685; H10W 90/701; H10W 90/724

(57) ABSTRACT

A redistribution layer substrate includes a top layer, a bottom layer, a plurality of intermediate layers, and a protective layer. The top layer includes a plurality of first conductive pads. The bottom layer includes a plurality of second conductive pads. The plurality of intermediate layers are deployed between the top layer and the bottom layer, and the plurality of intermediate layers includes a plurality of interlayer traces, respectively connecting each of the plurality of first conductive pads to each of the plurality of second conductive pads. The protective layer covers the top layer and includes via holes; and the via holes define a projection range on the top layer, and a portion of the plurality of first conductive pads are within the projection range.

### CROSS-REFERENCE TO RELATED APPLICATION

This non-provisional application claims the benefit of US provisional application Ser. No. 63/711,319, filed on Oct. 24, 2024 and claims the priority of Patent Application No. 114116834, filed in Taiwan, R.O.C. on May, 5, 2025. The entire of the above-mentioned patent applications is hereby incorporated by references herein and made a part of the specification.

### BACKGROUND

### Technical Field

The disclosure relates to a redistribution layer substrate structure, and particularly relates to a multilayer redistribution layer substrate structure.

### Related Art

As the size of semiconductors continues to reduce, semiconductor packaging processes face many challenges that will affect product reliability and design efficiency.

Firstly, in general, under bump metallization (UBM) is exposed to the surface of the substrate but lacks adequate protection mechanisms. Consequently, the UBM is prone to be damaged due to external environment or operational errors, resulting in decrease in process yields.

Secondly, a soldering area of the substrate also lacks a protective layer, which easily causes short circuit between solder balls, especially in high-density designs, and short circuit not only affects the process yield, but also further decreases the stability and reliability of the product.

Finally, a redistribution layer (RDL) structure of the substrate occupies a large amount of distribution area, which is difficult to meet the requirements for the minimum trace width and trace space of a small-size substrate. Moreover, the design requirements of impedance matching and insulation distance also limit the further reduction of the substrate size. These challenges show that traditional packaging technologies have significant limitations in meeting the needs of modern high-density and high-performance technologies, and there is an urgent need of technological breakthroughs to meet future development needs.

### SUMMARY

In view of this, the applicant proposes a redistribution layer substrate, including a top layer, a bottom layer, a plurality of intermediate layers, and a first protective layer. The top layer includes a plurality of first conductive pads. The bottom layer includes a plurality of second conductive pads. The plurality of intermediate layers are deployed between the top layer and the bottom layer, and the plurality of intermediate layers include a plurality of interlayer traces, respectively connecting each of the plurality of first conductive pads to each of the plurality of second conductive pads. The first protective layer covers the top layer and includes a first via hole, the first via hole defines a first projection range on the top layer, and a portion of the plurality of first conductive pads are within the first projection range.

The applicant also proposes a manufacturing method of a redistribution layer substrate, including: providing a multilayer board which includes a top layer and a bottom layer, where the top layer includes a plurality of first conductive pads, and the bottom layer includes a plurality of second conductive pads; forming a first protective layer above the top layer; and forming a first via hole in the first protective layer, where the first via hole defines a first projection range on the top layer, and a portion of the plurality of first conductive pads are within the first projection range.

### BRIEF DESCRIPTION OF THE DRAWINGS

FIG. 1A is a schematic diagram of a redistribution layer substrate with intralayer trace layout according to some embodiments.

FIG. 1B is a schematic diagram of a redistribution layer substrate with interlayer trace layout according to some embodiments.

FIG. 1C is a schematic diagram of a redistribution layer substrate with a chip deployed on a top layer according to some embodiments.

FIG. 2 is a flowchart of a manufacturing method of a redistribution layer substrate according to some embodiments.

FIG. 3 is a cross-sectional view of a redistribution layer substrate according to an Embodiment I.

FIG. 4 is a cross-sectional view of a redistribution layer substrate according to an Embodiment II.

FIG. 5 is a cross-sectional view of a redistribution layer substrate according to an Embodiment III.

FIG. 6 is a cross-sectional view of a redistribution layer substrate according to an Embodiment IV.

FIG. 7 is a cross-sectional view of a redistribution layer substrate according to an Embodiment V.

### DETAILED DESCRIPTION

The terms “a” or “an” used in this disclosure refer to elements and components of an invention. The terms are for the convenience of description and provide a basic concept of the invention. This description shall be understood to include one or at least one, and unless it is clearly stated otherwise, to include the singular as well as the plurality. When used in conjunction with the word “comprise” or “include” in the scope of the patent application, the term “a” may mean one or more than one.

Unless otherwise specified, spatial descriptions such as “up”, “down”, “left”, “right”, “front”, “back”, “inside”, and “outside” indicate the directions shown in the figures. It is to be understood that the spatial description used herein is for illustrative purposes only, and that the actual implementation of the structure described herein can be spatially configured in any opposite direction, and this restriction does not change the advantages of the embodiments of the disclosure.

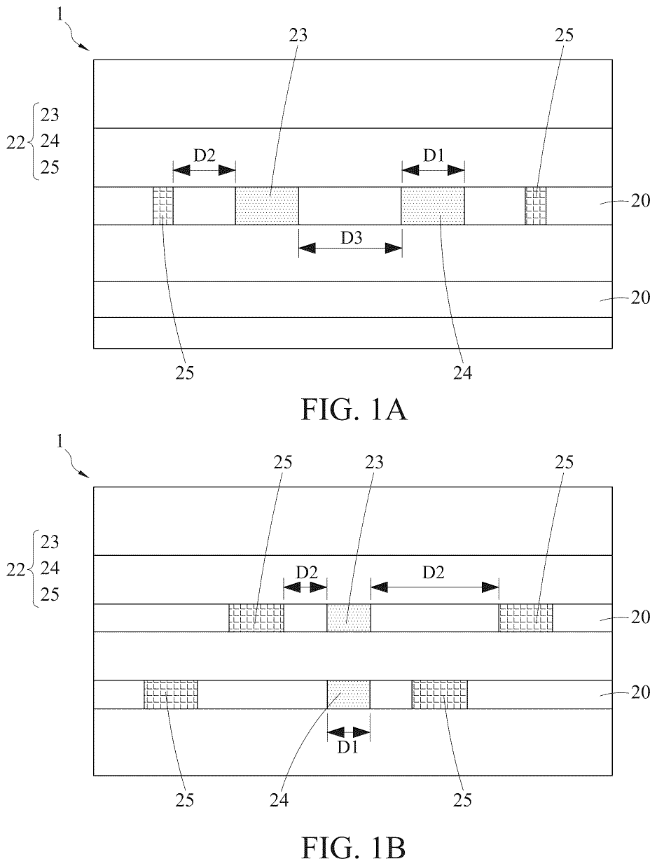

FIG. 1a is a schematic diagram of a redistribution layer substrate with intralayer trace layout according to some embodiments, and FIG. 1A is referred to. The redistribution layer substrate 1 includes at least one intermediate layer 20, and in this embodiment, an intralayer trace 22 of the intermediate layer 20 includes a first signal line 23, a second signal line 24 and ground lines 25. In this embodiment, the first signal line 23, the second signal line 24 and the ground lines 25 are located in the same intermediate layer 20, the signal lines have trace width D1, a ground trace space D2 is formed between the signal lines and the ground lines 25, and a signal trace space D3 is formed between the first signal line 23 and the second signal line 24. The ground trace space D2 and the signal trace space D3 are limited by the trace width D1, for example, the ground trace space D2 (the signal trace space D3) is the multiple of the trace width D1. When the distribution of the intralayer trace 22 is more complex, the area for distribution on the intermediate layer 20 is larger, and as a result, the size of the redistribution layer substrate 1 is enlarged. FIG. 1B is a schematic diagram of a redistribution layer substrate with interlayer trace layout according to some embodiments, and FIG. 1B is referred to. In this embodiment, the redistribution layer substrate 1 includes at least two intermediate layers 20, the intralayer trace 22 of one intermediate layer 20 includes the first signal line 23 and the ground lines 25, and the intralayer trace 22 of the other intermediate layer 20 includes the second signal line 24 and the ground lines 25. In view of the configuration of the interlayer trace layout, the area of the intermediate layers 20 mainly refers to the trace width D1 and the ground trace space D2. In addition, the first signal line 23 and the second signal line 24 are isolated by the intermediate layers 20, which reduces the area of a group of trace width D1 and the signal trace space D3, so that the area of the intermediate layers 20 in FIG. 1B can be smaller than that of the intermediate layers 20 in FIG. 1A. Therefore, the size of the redistribution layer substrate 1 is remarkably reduced.

FIG. 1C is a schematic diagram of a redistribution layer substrate with a chip deployed on a top layer according to some embodiments, FIG. 1A to FIG. 1C are referred to. In this embodiment, a chip 60 is arranged on the top layer 10 of the redistribution layer substrate 1, and the chip 60 includes a first signal end 61, a second signal end 62 and a grounding end 63 which are different pins of the chip 60. The first signal end 61 is electrically connected to the first signal line 23 in FIG. 1A or FIG. 1B, the second signal end 62 is electrically connected to the second signal line 24 in FIG. 1A or FIG. 1B, and the grounding end 63 is electrically connected to the ground lines 25 in FIG. 1A or FIG. 1B. As described above, the interlayer trace layout in FIG. 1B not only meets the requirement for trace isolation between the first signal line 23 and the second signal line 24, but also takes into account the technical requirement for reducing the size of the redistribution layer substrate 1. However, in this embodiment, the limitation of the interlayer trace layout refers to the occupation of the number of layers of the substrate, so it is needed to increase the number of available layers of the redistribution layer substrate 1, excepting to using the intralayer space as much as possible.

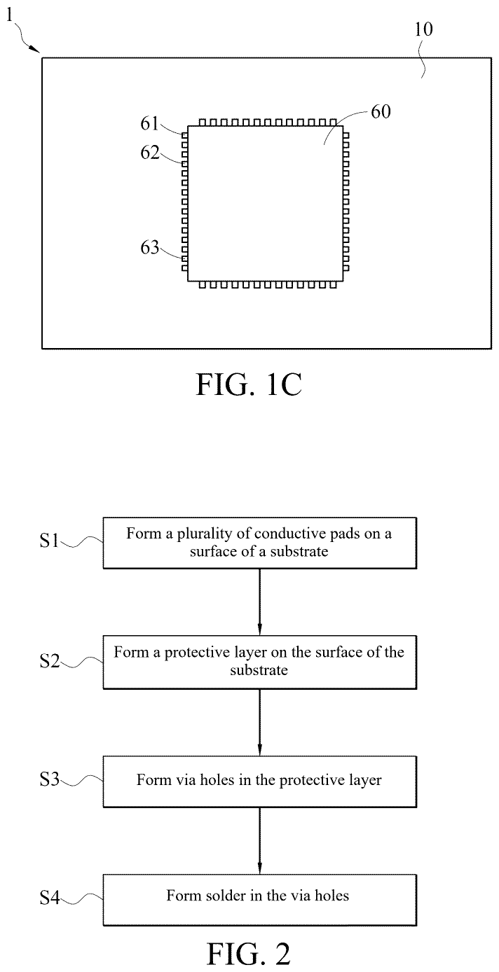

FIG. 2 is a flowchart of a manufacturing method of a redistribution layer substrate according to some embodiments, and FIG. 2 is referred to. In this embodiment, according to the manufacturing method of a redistribution layer substrate, a plurality of conductive pads are formed on the surface of the redistribution layer substrate (step S1). The substrate can be a multi-layer board, and the multi-layer board includes a top layer, an intermediate layer and a bottom layer. The intermediate layer is arranged between the top layer and the bottom layer, and the intermediate layer includes an interlayer trace 21, such as an RDL trace. The material of the substrate can be, but not limited to, polyimide, glass fiber, silicon (Si), silicon dioxide (SiO₂), silicon carbide (SiC) or glass. The conductive pads are made of conductive materials, such as but not limited to metal, alloy, graphene or conductive polymer. The conductive pads are electrically connected to the interlayer trace 21, for example, the conductive pads are UBMs arranged on the top layer of the redistribution layer substrate 1; or the conductive pads are welding pads arranged on the bottom layer of the redistribution layer substrate 1. The UBMs or the welding pads are electrically connected to the interlayer trace 21 of the intermediate layer of the redistribution layer substrate 1. The forming method of the conductive pads can be, but not limited to, micro-lithography, electroplating, chemical plating, chemical vapor deposition, physical vapor deposition or printing processes.

In step S2, protective layers are formed on the surface of the substrate according to the manufacturing method of a redistribution layer substrate. The protective layers cover the surface of the substrate and the surfaces of the conductive pads. The surface of the substrate is not limited to the surface of the top layer or bottom layer of the substrate. The materials of the protective layers are selected from the group consisting of polyimide, polyamide, polyethylene glycol terephthalate, polytetrafluoroethylene, a perfluoroalkyl vinyl ether copolymer, a fluoroplastic film, polyesterimide, polyvinyl butyral, polyether-ether-ketone, epoxy resin, solder resist ink and a combination thereof. In some embodiments, the thickness of the protective layers is equal to or greater than the trace width D1 of the signal lines. The forming method of the protective layer can be, but not limited to, chemical vapor deposition, physical vapor deposition, coating, spraying, press fit, printing or dipping processes.

In step S3, via holes are formed in the protective layers according to the manufacturing method of a redistribution layer substrate. In this embodiment, the via holes penetrate through the protective layers, so that the surface (the surface of the top layer or bottom layer) of the redistribution layer substrate 1 covered by the protective layers is exposed out of the via hole range. The forming method of the via holes can be, but not limited to, lithography, laser, chemical etching, plasma etching or mechanical drilling. Therefore, the conductive pads are covered by the protective layers, and only a portion of the plurality of conductive pads are exposed out of the via hole range. In some embodiments, the portion refers to one or more conductive pads among the plurality of conductive pads, for example, the top layer has 100 UBMs, among which, 20 UBMs are exposed within the via hole range, and the rest 80 UBMs are covered by the protective layers. In some embodiments, the portion refers to local surface areas of the conductive pads, for example, the surface area of one or more of the UBMs is 10 μm², the area of the inner range of the via holes is 2 μm², and the surface area of the one or more of the UBMs exposed out of the via holes is a value greater than 0 and less than or equal to 2 μm².In this embodiment, the local surface area of one or more conductive pads can be exposed out through one or more via holes.

In step S4, solder is formed within the via holes according to the manufacturing method of a redistribution layer substrate. The solder can be pre-welding pads 42 or solder balls 52, which are arranged above the via holes and electrically connected to the conductive pads below the protective layers through the via holes. The forming method of the solder can be, but not limited to, printing, spot soldering, solder ball placement, chemical vapor deposition, or physical vapor deposition processes. The solder can be electrically connected to the conductive pads by a soldering process, and the soldering process may include, but not limited to, the use of a hot air gun, a heating plate, reflow soldering, spot welding, ultrasonic wave, or laser processing.

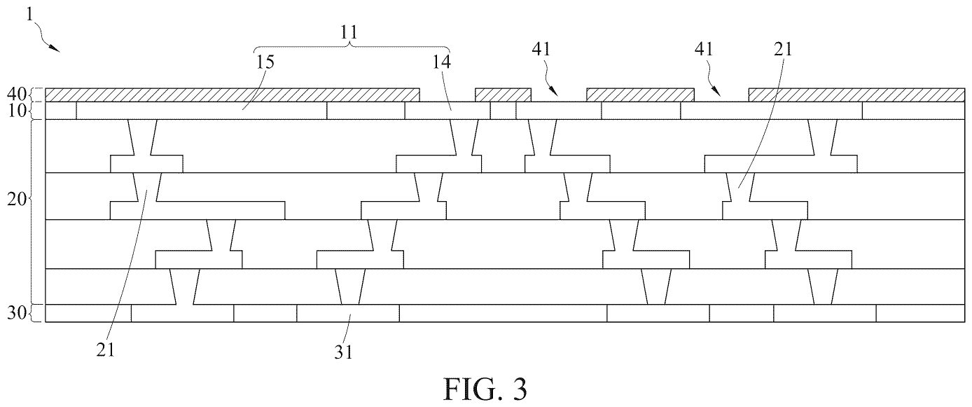

FIG. 3 is a cross-sectional view of a redistribution layer substrate according to an Embodiment I, and FIG. 3 is referred to. In this embodiment, the redistribution layer substrate 1 includes the top layer 10, the intermediate layer 20, a bottom layer 30 and a first protective layer 40. The top layer 10 includes a plurality of first conductive pads 11. In this embodiment, the first conductive pads 11 are the UBMs, and the top layer 10 of the redistribution layer substrate 1 includes 4 UBMs in total. The bottom layer 30 includes a plurality of second conductive pads 31. In this embodiment, the second conductive pads 31 are welding pads, and the bottom layer 30 of the redistribution layer substrate 1 includes 4 welding pads in total. The intermediate layer 20 is arranged between the top layer 10 and the bottom layer 30. In this embodiment, there are 4 intermediate layers 20 in total, including 4 groups of interlayer traces 21, respectively connecting each of the first conductive pads 11 to each of the second conductive pads 31. It is to be known that this embodiment takes the first conductive pads 11 refer to the UBMs on the top layer 10 of the redistribution layer substrate 1 as an example, but the first conductive pads can also refer to the welding pads on the bottom layer 30 of the redistribution layer substrate 1 in another embodiment. In other words, the up and down directions shown in FIG. 3 is not necessarily the relationship between the top surface and the bottom surface of a redistribution layer substrate 1.

The first protective layer 40 covers the top layer 10 and includes first via holes 41. In this embodiment, the first protective layer 40 includes 3 first via holes 41. Each first via hole 41 defines a first projection range on the top layer 10 of the redistribution layer substrate 1. As shown in FIG. 3, the projection range can refer to the projection of the via holes on the surface of the top layer 10 along the up-down direction in the figure, such as the projection on the upper surface of the top layer 10 and/or the projection on the upper surface of the first conductive pad 11. A portion of the plurality of first conductive pads 11 are within the first projection range; in this embodiment, 3 first conductive pads 11 on the right side of the top layer 10 of the redistribution layer substrate 1 are observed, the local surface area of any first conductive pad 11 is within the via hole range, the rest surface area is outside the via hole ranges (namely covered by the first protective layer 40), and such first conductive pads 11 are defined as third secondary conductive pads 14; and the first conductive pad 11 on the leftmost side of the top layer 10 of the redistribution layer substrate 1 is observed, the whole surface area of the first conductive pad 11 is outside the via hole range (namely covered by the first protective layer 40), and such first conductive pad 11 is defined as fourth secondary conductive pads 15.

In some embodiments, the redistribution layer substrate 1 is provided with the third secondary conductive pads 14 and the fourth secondary conductive pad 15 at the same time. The third secondary conductive pads 14 can be used for connecting the chip 60 so as to transmit a signal to the chip 60 or receive the signal from the chip 60. The fourth secondary conductive pad 15 can be used as the trace; and specifically, the fourth secondary conductive pad 15 can form the trace on the top layer 10 of the redistribution layer substrate 1, the trace can be used as the first signal line 23 shown in FIG. 1B, and one intermediate layer 20 of the redistribution layer substrate 1 can include the intralayer trace 22, namely it is used as the second signal line 24 shown in FIG. 1B. In this embodiment, the top layer 10 of the redistribution layer substrate 1 includes the UBMs (the third secondary conductive pads 14) and the trace (the fourth secondary conductive pad 15) at the same time, where the UBMs are not completely covered by the first protective layer 40 and can be connected to the chip 60, and the traces are completely covered by the first protective layer 40, which allows signal transmission and avoid oxidation or damage. Therefore, the number of available layers for interlayer trace layout of the redistribution layer substrate 1 is increased.

In this embodiment, the fourth secondary conductive pad 15 can be used as the first signal line 23 or the ground lines 25, and is electrically connected to the chip 60. Therefore, some of the signal lines (or the ground lines 25) from the plurality of traces of the chip 60 can be transmitted through the intralayer trace 22 of the intermediate layer 20, and the rest signal lines (or the ground lines 25) can be transmitted through the trace formed by the fourth secondary conductive pad 15, so that the limitation to the insulation distance among the layers is reduced. In some embodiments, the dimension of the third secondary conductive pads 14 is greater than 60 μm, and the inner dimension of the first via holes 41 is smaller than 60 μm, and therefore, the third secondary conductive pads 14 are partially covered by the first protective layer 40. Therefore, the UBMs can be protected by the first protective layer 40, and thus the damage caused by external environment or operation errors is avoided.

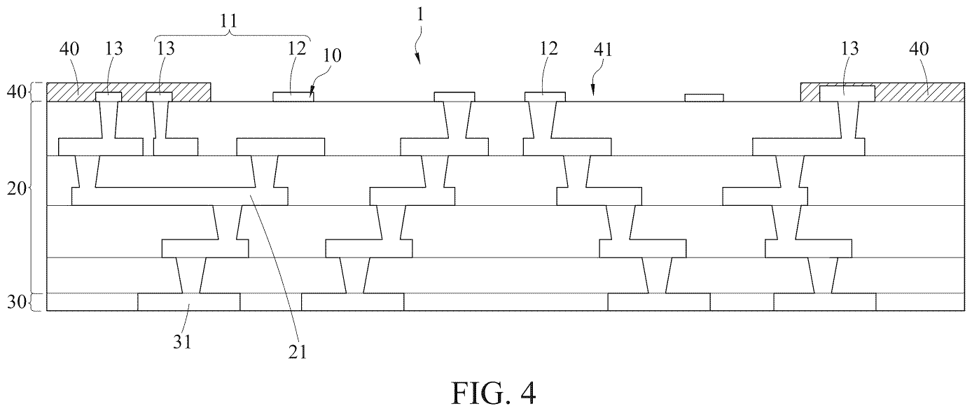

FIG. 4 is a cross-sectional view of a redistribution layer substrate according to an Embodiment II, and FIG. 4 is referred to. The main difference between this embodiment and the Embodiment I is the configuration relationship between the holes and the first conductive pads 11. In this embodiment, the first conductive pads 11 are the UBMs, the top layer 10 of the redistribution layer substrate 1 includes 4 UBM bump pads and 3 signal traces, the second conductive pads 31 are welding pads, and the bottom layer 30 of the redistribution layer substrate 1 includes 4 welding pads in total. There are 4 intermediate layer 20 in total, including 4 groups of interlayer traces 21, respectively connecting the plurality of first conductive pads 11 to the plurality of second conductive pads 31. It is to be known that the up and down directions shown in FIG. 4 is not necessarily the relationship between the top surface and the bottom surface of the redistribution layer substrate 1, so the first conductive pads 11 shown in FIG. 4 can also be the welding pads, and the second conductive pads 31 are UBMs.

The first protective layer 40 covers the top layer 10 and includes first via holes 41. In this embodiment, the first protective layer 40 includes 1 first via hole 41. The first via hole 41 defines the first projection range on the top layer 10 of the redistribution layer substrate 1. A portion of the plurality of first conductive pads 11 are within the first projection range; in this embodiment, the 4 first conductive pads 11 in the middle of the top layer 10 of the redistribution layer substrate 1 are observed, the whole surface area of any of these first conductive pads 11 is within the via hole range, and such first conductive pads 11 are defined as first secondary conductive pads 12; and 3 first conductive pads 11 on the left side and the right side of the top layer 10 of the redistribution layer substrate 1 are observed, the whole surface areas of these first conductive pads 11 are outside the via hole range (namely, covered by the first protective layer 40), and such first conductive pads 11 are defined as second secondary conductive pads 13.

In some embodiments, the redistribution layer substrate 1 is provided with the first secondary conductive pads 12 and the second secondary conductive pads 13 at the same time. The first secondary conductive pads 12 can be used for connecting the chip 60 so as to transmit the signal to the chip 60 or receive the signal from the chip 60. The second secondary conductive pads 13 can be used as the traces, as described in the Embodiment I, the traces can be used as the first signal line 23 in FIG. 1B, and one intermediate layer 20 of the redistribution layer substrate 1 can include the intralayer trace 22, namely, it is used as the second signal line 24 in FIG. 1B. Therefore, the number of available layers for interlayer trace layout of the redistribution layer substrate 1 is increased. In this embodiment, the second secondary conductive pads 13 can be used as the first signal line 23 or the ground lines 25, and are electrically connected to the chip 60. Based on that, some signal lines (or the ground lines 25) from the plurality of traces of the chip 60 can be transmitted through the intralayer trace 22 of the intermediate layer 20, and the rest signal lines (or the ground lines 25) can be transmitted through the traces formed by the second secondary conductive pads 13, so that the limitation to the insulation distance among the layers is reduced. In some embodiments, the dimension of the first secondary conductive pads 12 is smaller than 60 μm, the inner dimension of the first via holes 41 is larger than 60 μm, thus one or more first secondary conductive pads 12 are completely exposed out of the first via hole 41, and the rest one or more first secondary conductive pads 12 are completely covered by the first protective layer 40. Therefore, micro UBMs (the first secondary conductive pads 12) can be used for connecting the chip 60, and the second secondary conductive pads 13 below the first protective layer 40 can be used for transmitting the signal.

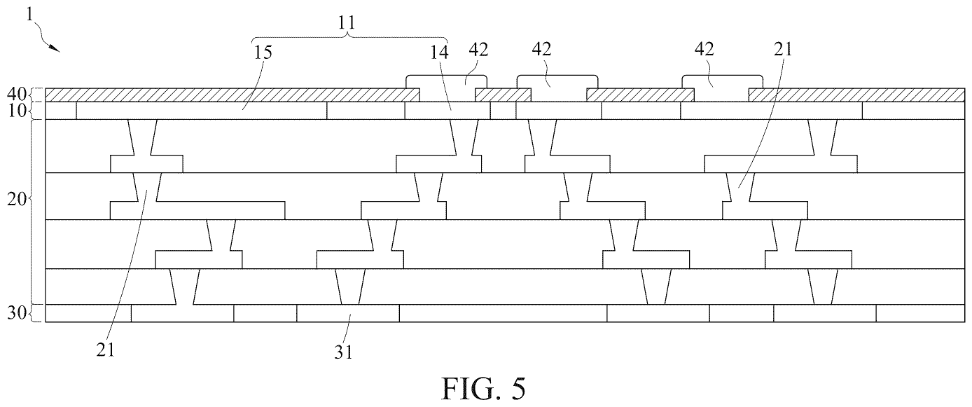

FIG. 5 is a cross-sectional view of a redistribution layer substrate according to an Embodiment III, and FIG. 5 is referred to. In this embodiment, the redistribution layer substrate 1 includes the top layer 10, the intermediate layer 20, the bottom layer 30, the first protective layer 40 and the pre-welding pads 42. The pre-welding pads 42 are arranged above the first protective layer 40 and are connected to the third secondary conductive pads 14 through the first via holes 41. The pre-welding pads 42 protect the third secondary conductive pads 14 arranged in the first via holes 41 from being damaged, and the pre-welding pads can be melted and electrically connected to the chip 60 or other electronic elements in the soldering process. In some other embodiments, the redistribution layer substrate 1 includes the top layer 10, the intermediate layer 20, the bottom layer 30, the first protective layer 40 and the solder balls (not shown in the figure). The solder balls are arranged above the first protective layer 40 and are connected to the third secondary conductive pads 14 through the first via holes 41. The solder balls can be melted and electrically connected to other substrates or electronic elements in the soldering process, and moreover, the first protective layer 40 can prevent the solder balls from being too close and can prevent the melted solder ball material from being diffused to cause short circuit among the first conductive pads 11.

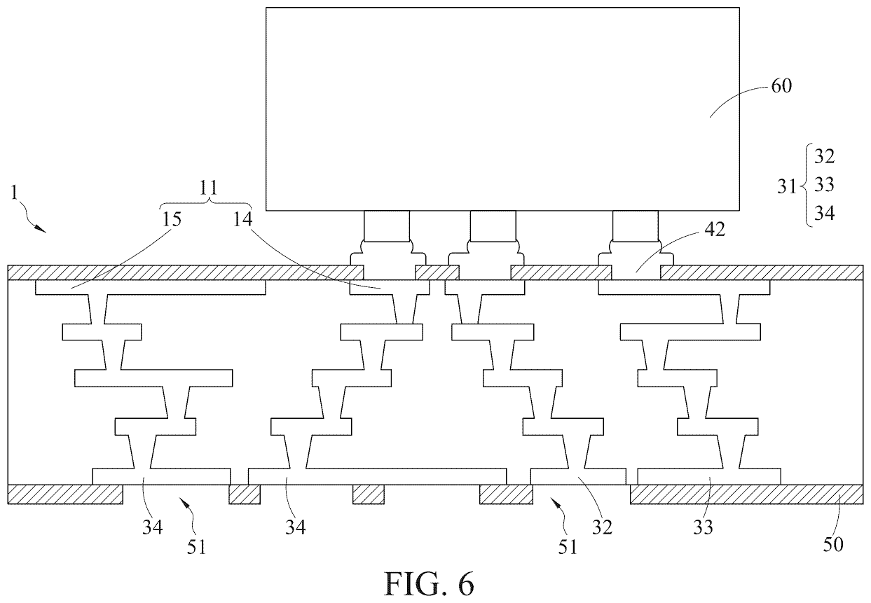

FIG. 6 is a cross-sectional view of a redistribution layer substrate in an Embodiment IV, and FIG. 6 is referred to. In this embodiment, the redistribution layer substrate 1 includes the top layer 10, the intermediate layer 20, the bottom layer 30, the first protective layer 40 and a second protective layer 50. The second protective layer 50 covers the bottom layer 30 and includes second via holes 51. In this embodiment, the second protective layer 50 includes 4 second via holes 51. Each second via hole 51 defines a second projection range on the bottom layer 30 of the redistribution layer substrate 1. As shown in FIG. 6, the projection range can refer to the projection of the via holes on the surface of the bottom layer 30 along the up-down direction in the figure, such as the projection on the lower surface of the bottom layer 30 and/or the projection on the lower surface of the second conductive pad 31. A portion of the plurality of second conductive pads 31 are within the second projection range. In this embodiment, 2 second conductive pads 31 on the left side of the bottom layer 30 of the redistribution layer substrate 1 are observed, the local surface area of any of these second conductive pads 31 is within the via hole range, the rest surface area is outside the via hole range (namely covered by the second protective layer 50), and such second conductive pads 31 are defined as seventh secondary conductive pads 34; the second conductive pad 31 on the rightmost side of the bottom layer 30 of the redistribution layer substrate 1 is observed, the whole surface area of this second conductive pad 31 is outside the via hole range (namely covered by the second protective layer 50), and such second conductive pad 31 is defined as a sixth secondary conductive pad 33; and the second conductive pads 31 on the second right side of the bottom layer 30 of the redistribution layer substrate 1 is observed, the whole surface area of this second conductive pads 31 is within the via hole range, and such second conductive pad 31 is defined as fifth secondary conductive pads 32.

The structures, functions and effects of the second conductive pads 31 can be designed and configured with reference to detailed description of the first conductive pads 11 in the above embodiments. In the Embodiment IV, the redistribution layer substrate 1 includes the first conductive pads 11 and the second conductive pads 31 at the same time, where the first conductive pads 11 can be used for connecting the chip 60 or other electronic elements, and the second conductive pads 31 can be used for connecting other substrates or electronic elements. In this embodiment, the fourth secondary conductive pad 15 and the sixth secondary conductive pad 33 can be treated as the first signal line 23 or the second signal line 24 in FIG. 1B, so that the number of available layers for interlayer trace layout of the redistribution layer substrate 1 is increased.

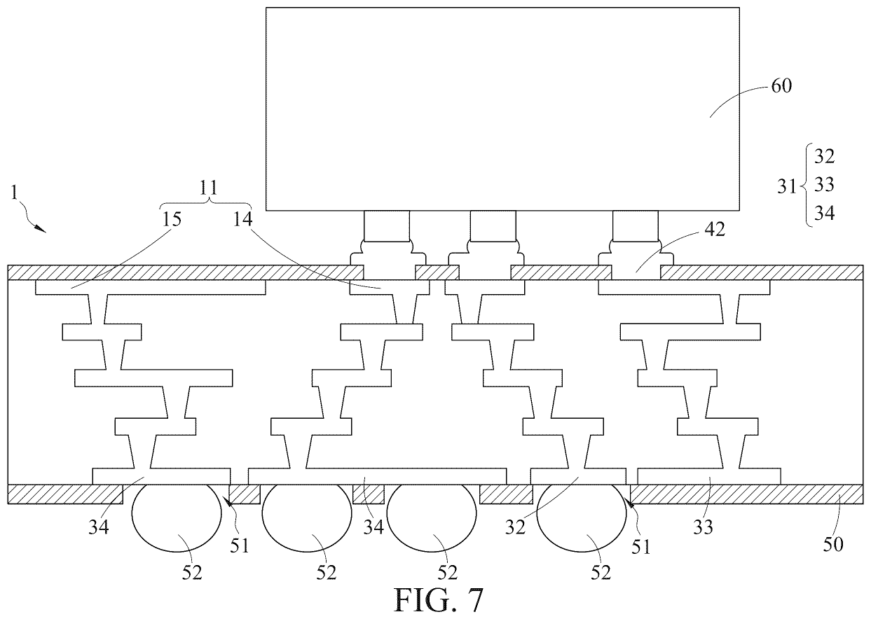

FIG. 7 is a cross-sectional view of a redistribution layer substrate according to an Embodiment V, and FIG. 7 is referred to. In this embodiment, the redistribution layer substrate 1 includes the top layer 10, the intermediate layer 20, the bottom layer 30, the first protective layer 40, the second protective layer 50, the pre-welding pads 42 and the solder balls 52. The pre-welding pads 42 are arranged above the first protective layer 40 and are connected to the third secondary conductive pads 14 through the first via holes 41. The solder balls 52 are arranged below the second protective layer 50 and are connected to the fifth secondary conductive pads 32 and/or the seventh secondary conductive pads 34 through the second via holes 51. In some embodiments, the first protective layers 40 are selected from the group consisting of polyimide, polyamide, polyethylene glycol terephthalate, polytetrafluoroethylene, a perfluoroalkyl vinyl ether copolymer, a fluoroplastic film, polyesterimide, polyvinyl butyral, polyether-ether-ketone, epoxy resin and a combination thereof, and the second protective layer 50 is solder mask ink. Therefore, the first protective layer 40 is used for protecting the first conductive pads 11 in the substrate packaging process from being damaged, and the second protective layer 50 is used for preventing the solder from being diffused in the soldering process to cause short circuit to the second conductive pads 31.

Although the disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A redistribution layer substrate, comprising:
a top layer comprising a plurality of first conductive pads;
a bottom layer comprising a plurality of second conductive pads;
a plurality of intermediate layers deployed between the top layer and the bottom layer, the plurality of intermediate layers comprising a plurality of interlayer traces, respectively connecting each of the plurality of first conductive pads to each of the plurality of second conductive pads; and
a protective layer covering the top layer and comprising a first via hole, wherein the first via hole defines a first projection range on the top layer, and a portion of the plurality of first conductive pads are within the first projection range.

2. The redistribution layer substrate according to claim 1, wherein the plurality of first conductive pads comprise a plurality of first secondary conductive pads and a plurality of second secondary conductive pads; the plurality of first secondary conductive pads are within the first projection range; and the plurality of second secondary conductive pads are outside the first projection range.

3. The redistribution layer substrate according to claim 2, wherein the dimension of the plurality of first secondary conductive pads is smaller than 60 μm.

4. The redistribution layer substrate according to claim 2, further comprising a chip, wherein the chip comprises a first signal end, a second signal end and a grounding end; one of the plurality of intermediate layers comprises a plurality of intralayer traces; the first signal end is connected to one of the plurality of second secondary conductive pads; the second signal end is connected to one of the plurality of intralayer traces; and the grounding end is connected to another of the plurality of the second secondary conductive pads and another of the plurality of intralayer traces.

5. The redistribution layer substrate according to claim 1, wherein the plurality of first conductive pads comprise a third secondary conductive pad, and the local surface area of the third conductive pad is within the first projection range.

6. The redistribution layer substrate according to claim 5, further comprising a pre-welding pad arranged above the first protective layer and connected to the third secondary conductive pad through the first via hole.

7. The redistribution layer substrate according to claim 5, wherein the dimension of the third secondary conductive pad is greater than 60 μm, and the inner dimension of the first via hole is smaller than 60 μm.

8. The redistribution layer substrate according to claim 5, further comprising a chip, wherein the plurality of first conductive pads comprise a plurality of fourth secondary conductive pads, and whole surface areas of the plurality of fourth secondary conductive pads are outside the first projection range; the chip comprises a first signal end, a second signal end and a grounding end; one of the plurality of intermediate layers comprises a plurality of intralayer traces; the first signal end is connected to one of the plurality of fourth secondary conductive pads; the second signal end is connected to one of the plurality of intralayer traces;
and the grounding end is connected to another of the plurality of fourth secondary conductive pads and another of the plurality of intralayer traces.

9. The redistribution layer substrate according to claim 1, wherein the first protective layer is selected from the group consisting of polyimide, polyamide, polyethylene glycol terephthalate, polytetrafluoroethylene, a perfluoroalkyl vinyl ether copolymer, a fluoroplastic film, polyesterimide, polyvinyl butyral, polyether-ether-ketone, epoxy resin, solder resist ink and a combination thereof.

10. The redistribution layer substrate according to claim 1, further comprising a second protective layer covering the bottom layer and comprising a second via hole, wherein the second via hole defines a second projection range on the bottom layer; and a portion of the plurality of second conductive pads are within the second projection range.

11. The redistribution layer substrate according to claim 10, wherein the plurality of second conductive pads comprise a plurality of fifth secondary conductive pads and a plurality of sixth secondary conductive pads; the plurality of fifth secondary conductive pads are within the second projection range; and the plurality of sixth secondary conductive pads are outside the second projection range.

12. The redistribution layer substrate according to claim 10, wherein the plurality of second conductive pads comprise a seventh secondary conductive pad; and the local surface area of the seventh secondary conductive pad is within the second projection range.

13. The redistribution layer substrate according to claim 12, further comprising a pre-welding pad and a solder ball, wherein the plurality of first conductive pads comprise a third secondary conductive pad, and the local surface area of the third secondary conductive pad is within the first projection range; the pre-welding pad is arranged above the first protective layer and is connected to the third secondary conductive pad through the first via hole; and the solder ball is arranged below the second protective layer and is connected to the seventh secondary conductive pad through the second via hole.

14. The redistribution layer substrate according to claim 13, wherein the first protective layer is selected from the group consisting of polyamide imide, polyamide, polyethylene glycol terephthalate, polytetrafluoroethylene, a perfluoroalkyl vinyl ether copolymer, a fluoroplastic film, polyesterimide, polyvinyl butyral, polyether-ether-ketone, epoxy resin and a combination thereof; and the second protective layer is solder mask ink.

15. A manufacturing method of a redistribution layer substrate, comprising:
providing a multilayer board comprising a top layer and a bottom layer, wherein the top layer comprises a plurality of first conductive pads, and the bottom layer comprises a plurality of second conductive pads;
forming a first protective layer above the top layer; and
forming a first via hole in the first protective layer, wherein the first via hole defines a first projection range on the top layer, and a portion of the plurality of first conductive pads are within the first projection range.

16. The manufacturing method of a redistribution layer substrate according to claim 15, wherein the plurality of first conductive pads comprise a plurality of first secondary conductive pads and a plurality of second secondary conductive pads; the plurality of first secondary conductive pads are within the first projection range; and the plurality of second secondary conductive pads are outside the first projection range.

17. The manufacturing method of a redistribution layer substrate according to claim 15, wherein the plurality of first conductive pads comprise a third secondary conductive pads, and the local surface area of the third secondary conductive pad is within the first projection range.

18. The manufacturing method of a redistribution layer substrate according to claim 17, further comprising: forming a pre-welding pad above the first protective layer, wherein the pre-welding pad is connected to the third secondary conductive pad through the first via hole.

19. The manufacturing method of a redistribution layer substrate according to claim 15, further comprising:
forming a second protective layer below the bottom layer; and
forming a second via hole in the second protective layer, wherein the second via hole defines a second projection range on the bottom layer, and a portion of the plurality of second conductive pads are within the second projection range.

20. The manufacturing method of a redistribution layer substrate according to claim 19, further comprising: forming a solder ball below the second protective layer, wherein the solder ball is connected to one of the plurality of second conductive pads through the second via hole.
